(19) United States
(12) Patent Application Publication
(10) Pub. No.: US 2024/0347403 A1
(43) Pub. Date: Oct. 17, 2024

(54) SEMICONDUCTOR DEVICE

(71) Applicant: Mitsubishi Electric Corporation, Tokyo (JP)

(72) Inventor: Takeshi HIGASHIHATA, Tokyo (JP)

(73) Assignee: Mitsubishi Electric Corporation, Tokyo (JP)

(21) Appl. No.: 18/689,707

(22) PCT Filed: Dec. 16, 2021
(86) PCT No.: PCT/JP2021/046597

§ 371 Date: Mar. 6, 2024

(51) Int. Cl. H01L 23/16; H01L 23/00; H01L 23/10; H01L 23/14; H01L 23/31; H01L 23/36; H01L 25/065; H01L 29/16; H01L 29/20

(52) U.S. Cl. CPC H01L 23/16; H01L 23/10; H01L 23/142; H01L 23/3107; H01L 23/36; H01L 24/32; H01L 24/48; H01L 25/0655; H01L 29/1602; H01L 29/1608; H01L 29/2003; H01L 2224/32245; H01L 2224/48137

(57) ABSTRACT

An insulation substrate (2) is provided on a beat dissipation plate (1). A semiconductor chip (4) is mounted on the insulation substrate (2). A case (7) is adhered to a peripheral portion of the heat dissipation plate (1) with a silicone adhesive (8) to surround the insulation substrate (2) and the semiconductor chip (4). A wire bond (10) is provided on the heat dissipation plate (1) between an outer periphery of an insulation layer (2a) in the insulation substrate (2) and an inner wall of the case (7).

### FIELD

The present disclosure relates to a semiconductor device.

### BACKGROUND

A semiconductor device in which a case adheres to a peripheral portion of a heat dissipation plate with a silicone adhesive to surround an insulation substrate has been used. It has been proposed to provide a projection of a resist on the heat dissipation plate between the insulation substrate and the case to stop inflow of the silicone adhesive extruded during the adhesion of the case (see, e.g., PTL 1).

### CITATION LIST

### Patent Literature

[PTL 1] WO 2017/094189

### SUMMARY OF THE INVENTION

### Problem to be Solved by the Invention

However, a liquid resist is cured to produce the projection. Accordingly, the height of the projection is difficult to ensure. Therefore, the inflow of the silicone adhesive cannot be sufficiently stopped by the projection of the resist. Accordingly, the silicone adhesive extruded during the adhesion of the case may flow under an insulation layer of the insulation substrate so that a void occurs. There has been a problem that partial discharge occurs due to the void, resulting in a decrease in dielectric voltage resistance and a deterioration in reliability.

The present disclosure has been made to solve the above-described problem, and has an object to obtain a semiconductor device enabling an improvement in reliability.

### Solution to Problem

A semiconductor device according to the present disclosure includes: a heat dissipation plate: an insulation substrate provided on the heat dissipation plate; a semiconductor chip mounted on the insulation substrate; a case adhered to a peripheral portion of the heat dissipation plate with a silicone adhesive to surround the insulation substrate and the semiconductor chip; and a wire bond provided on the heat dissipation plate between an outer periphery of an insulation layer in the insulation substrate and an inner wall of the case.

### Advantageous Effects of Invention

In the present disclosure, the wire bond blocks the silicone adhesive extruded toward the inside of the case. As a result, the silicone adhesive can be prevented from flowing under the insulation layer in the insulation substrate. Accordingly, occurrence of a void and occurrence of partial discharge caused thereby are suppressed, thereby preventing a decrease in dielectric voltage resistance and enabling an improvement in reliability.

### BRIEF DESCRIPTION OF THE DRAWINGS

FIG. 1 is a plan view illustrating a semiconductor device according to an embodiment 1.

FIG. 2 is a cross-sectional view taken along a line I-II illustrated in FIG. 1.

FIG. 3 is a cross-sectional view illustrating a semiconductor device according to the comparative example 1.

FIG. 4 is a diagram illustrating the semiconductor device according to the embodiment 1 with its part cut out along the wire bond.

FIG. 5 is a diagram illustrating a comparison between respective wire bonds in the embodiment 1 and a comparative example 2.

FIG. 6 is a diagram illustrating a comparison between respective parts of semiconductor devices in an embodiment 2 and a comparative example 3.

### DESCRIPTION OF EMBODIMENTS

A semiconductor device according to the embodiments of the present disclosure will be described with reference to the drawings. The same components will be denoted by the same symbols, and the repeated description thereof may be omitted.

### Embodiment 1

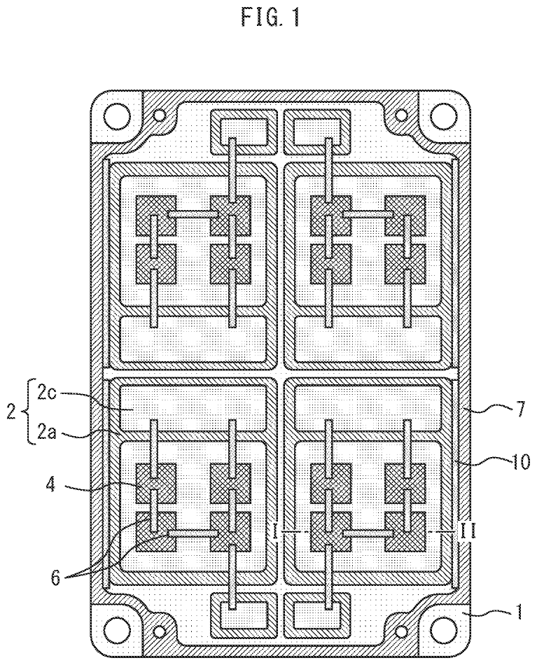

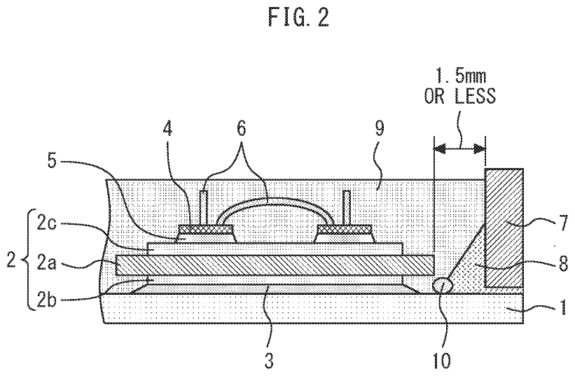

FIG. 1 is a plan view illustrating a semiconductor device according to an embodiment 1. FIG. 2 is a cross-sectional view taken along a line I-II illustrated in FIG. 1. A material for a heat dissipation plate 1 is Cu, Al, or an AlSiC composite material. An insulation substrate 2 is provided on the heat dissipation plate 1. The insulation substrate 2 includes an insulation layer 2a, a lower surface electrode 2b provided on a lower surface of the insulation layer 2a, and an upper surface electrode 2c provided on an upper surface of the insulation layer 2a. A material for the insulation layer 2a is AlN, Si₃N₄, or Al₂O₃. A material for the lower surface electrode 2b and the upper surface electrode 2c is a metal such as Cu or Al. The lower surface electrode 2b is bonded to an upper surface of the heat dissipation plate 1 with a solder 3.

A semiconductor chip 4 is mounted on the insulation substrate 2. A lower surface electrode of the semiconductor chip 4 is bonded to the upper surface electrode 2c in the insulation substrate 2 with a solder 5. A wire 6 is bonded to an upper surface electrode of the semiconductor chip 4.

A case 7 composed of PPS resin adheres to a peripheral portion of the heat dissipation plate 1 with a silicone adhesive 8 to surround the insulation substrate 2 and the semiconductor chip 4. The inside of the case 7 is filled with a sealing agent 9.

A wire bond 10 is provided on the beat dissipation plate 1 between an outer periphery of the insulation layer 2a in the insulation substrate 2 and an inner wall of the case 7. The wire bond 10 is arranged to be parallel to the outer periphery of the insulation layer 2a in a planar view. The height of a projection formed of a conventional resist is 10 to 50 μm, while the wire diameter of the wire bond 10 is 200 to 600 μm. A projection having a sufficient height can be easily formed by the wire bond 10.

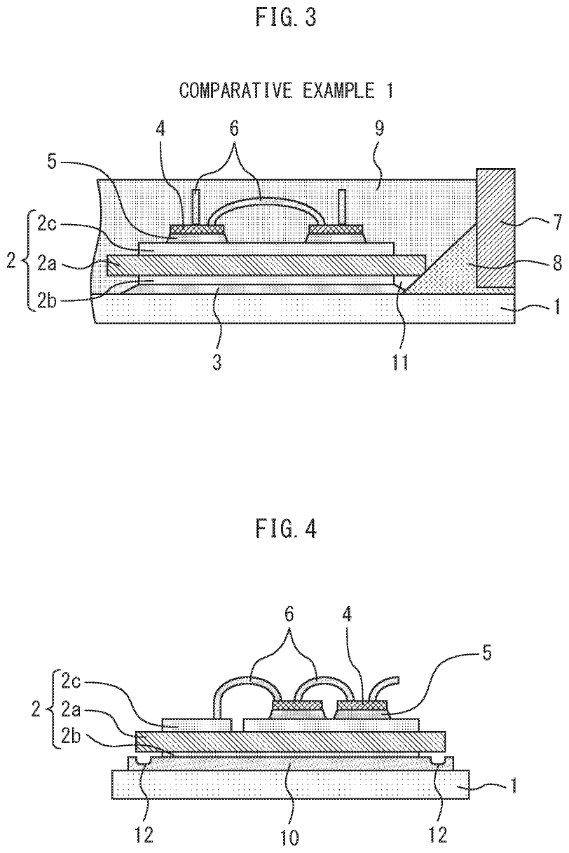

Then, an effect of the present embodiment will be described in comparison with that of a comparative example 1. FIG. 3 is a cross-sectional view illustrating a semiconductor device according to the comparative example 1. In the comparative example 1, the wire bond 10 is not provided. A silicone adhesive 8 is applied to a peripheral portion of a heat dissipation plate 1, and is extruded toward the inside and the outside of a case 7 during adhesion of the case 7. The silicon adhesive 8 extruded toward the inside of the case 7 flows under an insulation layer 2a in an insulation substrate 2 so that a void 11 occurs. Partial discharge occurs due to the void 11, resulting in a decrease in dielectric voltage resistance and a deterioration in reliability.

On the other hand, in the present embodiment, the wire bond 10 blocks the silicone adhesives 8 extruded toward the inside of the case 7. As a result, the silicone adhesive 8 can be prevented from flowing under the insulation layer 2a in the insulation substrate 2. Accordingly, occurrence of a void and occurrence of partial discharge caused thereby are suppressed, thereby preventing a decrease in dielectric voltage resistance and enabling an improvement in reliability.

FIG. 4 is a diagram illustrating the semiconductor device according to the embodiment 1 with its part cut out along the wire bond. The wire diameter of a portion, which is provided with a stitch 12, of the wire bond 10, decreases, whereby the height of the wire bond 10 partially decreases. The silicone adhesive 8 may flow in from the portion. Therefore, the wire bond 10 is not provided with the stitch 12 except at its start point and end point. This makes it possible to prevent the silicone adhesive 8 from flowing in. In this case, the wire bond 10 is not bonded to the heat dissipation plate 1 except at the start point and the end point, but is placed on the heat dissipation plate 1 while being stretched straight.

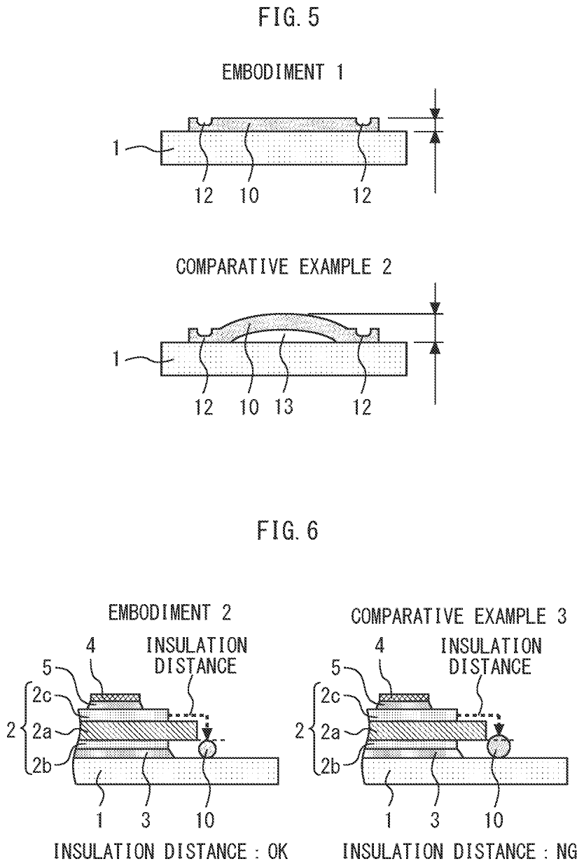

FIG. 5 is a diagram illustrating a comparison between respective wire bonds in the embodiment 1 and a comparative example 2. In the comparative example 2, a wire bond 10 has a loop shape. Accordingly, a silicon adhesive 8 flows in from a gap 13 between the wire bond 10 and a heat dissipation plate 1. On the other hand, in the embodiment 1, the wire bond 10 does not have a loop shape, but contacts the heat dissipation plate 1 at the start point to the end point. This eliminates the gap 13 between the wire bond 10 and the heat dissipation plate 1, thereby making it possible to prevent the silicone adhesive 8 from flowing in.

As a current capacity increases, the size of the semiconductor chip 4 increases, and the size of the insulation substrate 2 on which the semiconductor chip 4 is mounted also increases. Therefore, a distance between the outer periphery of the insulation layer 2a in the insulation substrate 2 and the inner wall of the case 7 is set to 1.5 mm or less. The insulation substrate 2 the size of which is enlarged by shortening the distance can be mounted, thereby making it possible to increase the current capacity while suppressing an external size of the semiconductor device.

The wire diameter of the wire bond 10 is preferably the same as the wire diameter of the wire 6 connected to the semiconductor chip 4. As a result, a wire bonding device and a wire material can be shared, thereby making it possible to expect a decrease in introduction cost, suppression of a stage replacement time period, and a decrease in material cost.

### Embodiment 2

FIG. 6 is a diagram illustrating a comparison between respective parts of semiconductor devices in an embodiment 2 and a comparative example 3. A spacing between an insulation layer 2a and a heat dissipation plate 1 is a total of the thickness of a lower surface electrode 2b and the thickness of a solder 3, i.e., 300 to 600 μm. In the comparative example 3, the wire diameter of a wire bond 10 exceeds a spacing between an insulation layer 2a and a heat dissipation plate 1. The wire bond 10 is bonded to the heat dissipation plate 1, and thus has the same potential as that of the heat dissipation plate 1. Therefore, in the comparative example 3, an insulation distance from an upper surface electrode 2c in an insulation substrate 2 to the heat dissipation plate 1 decreases, resulting in a decrease in dielectric voltage resistance. On the other hand, in the embodiment 2, the wire diameter of a wire bond 10 does not exceed the spacing between the insulation layer 2a and the heat dissipation plate 1. This prevents a decrease in dielectric voltage resistance and enables an improvement in reliability. Another configuration and effect are similar to those of the embodiment 1.

The semiconductor chip 4 is not limited to a semiconductor chip formed of silicon, but instead may be formed of a wide-bandgap semiconductor having a bandgap wider than that of silicon. The wide-bandgap semiconductor is, for example, a silicon carbide, a gallium-nitride-based material, or diamond. A semiconductor chip formed of such a wide-bandgap semiconductor has a high voltage resistance and a high allowable current density, and thus can be miniaturized. The use of such a miniaturized semiconductor chip enables the miniaturization and high integration of the semiconductor device in which the semiconductor chip is incorporated. Further, since the semiconductor chip has a high heat resistance, a radiation fin of a heatsink can be miniaturized and a water-cooled part can be air-cooled, which leads to further miniaturization of the semiconductor device. Further, since the semiconductor chip has a low power loss and a high efficiency, a highly efficient semiconductor device can be achieved.

### REFERENCE SIGNS LIST

1 heat dissipation plate; 2 insulation substrate; 2a insulation layer; 4 semiconductor chip; 6 wire; 7 case; 8 silicone adhesive; 10 wire bond; 12 stitch

1. A semiconductor device comprising:
a heat dissipation plate;
an insulation substrate provided on the heat dissipation plate;
a semiconductor chip mounted on the insulation substrate;
a case adhered to a peripheral portion of the heat dissipation plate with a silicone adhesive to surround the insulation substrate and the semiconductor chip; and
a wire bond provided on the heat dissipation plate between an outer periphery of an insulation layer in the insulation substrate and an inner wall of the case.

2. The semiconductor device according to claim 1, wherein the wire bond is arranged to be parallel to an outer periphery of the insulation layer in a planar view.

3. The semiconductor device according to claim 1, wherein the wire bond blocks the silicone adhesive extruded toward the inside of the case.

4. The semiconductor device according to claim 1, wherein the wire bond is not provided with any stitches except at a start point and an end point of the wire bond.

5. The semiconductor device according to claim 1, wherein the wire bond does not have a loop shape, but contacts the heat dissipation plate at a start point to an end point of the wire bond.

6. The semiconductor device according to claim 1, wherein a wire diameter of the wire bond does not exceed a spacing between the insulation layer and the heat dissipation plate.

7. The semiconductor device according to claim 1, further comprising a wire connected to the semiconductor chip, wherein a wire diameter of the wire bond is same as a wire diameter of the wire.

8. The semiconductor device according to claim 1, wherein a distance between an outer periphery of the insulation layer in the insulation substrate and an inner wall of the case is 1.5 mm or less.

9. The semiconductor device according to claim 1, wherein the semiconductor chip is formed of a wide-bandgap semiconductor.
